(19) United States
(12) Patent Application Publication
(10) Pub. No.: US 2015/0348973 A1
(43) Pub. Date: Dec. 3, 2015

(54) SEMICONDUCTOR INTEGRATED CIRCUIT (IC) DEVICE AND METHOD OF MANUFACTURING THE SAME

(71) Applicant: Renesas Electronics Corporation, Kawasaki-shi (JP)

(72) Inventors: Masashige MORITOKI, Kawasaki-shi (JP); Kenichi YAMAMOTO, Kawasaki-shi (JP)

(21) Appl. No.: 14/711,449

(22) Filed: May 13, 2015

(30) Foreign Application Priority Data
May 30, 2014 (JP) 2014-113487

(51) Int. Cl. H01L 27/108; H01L 29/417; H01L 29/66; H01L 29/78

(52) U.S. Cl. CPC H01L 27/10802; H01L 29/78; H01L 29/41783; H01L 29/6656; H01L 27/10844

(57) ABSTRACT

The charge retention characteristics of a semiconductor integrated circuit (IC) device are improved. A semiconductor integrated circuit (IC) device SM includes an n⁻-type semiconductor region that is formed, on an end of a gate electrode, on the main side of a semiconductor substrate, an n⁺-type semiconductor region that is provided on the main side of the semiconductor substrate and is formed on a silicon film having a top surface, and a side wall insulating film covering the side wall of the gate electrode and a part of the top surface of the silicon film. The semiconductor integrated circuit (IC) device further includes a silicide film formed on the top surface of the silicon film exposed from the side wall insulating film. The n⁺-type semiconductor region has the same conductivity type as the n⁻-type semiconductor region and has a higher concentration than the n⁻-type semiconductor region. The n⁻-type semiconductor region and the n⁺-type semiconductor region SD1 includes the source region or the drain region of a MISFET.

### CROSS-REFERENCE TO RELATED APPLICATIONS

The disclosure of Japanese Patent Application No. 2014-113487 filed on May 30, 2014 including the specification, drawings and abstract is incorporated herein by reference in its entirety.

The present invention relates to a semiconductor integrated circuit (IC) device and a method of manufacturing the same and relates to, for example, DRAM having a capacitive element (capacitor) or eDRAM containing DRAM having a capacitive element and a logic circuit.

### BACKGROUND

For example, DRAM in eDRAM (Embedded Dynamic Random Access Memory) has a plurality of DRAM cells, each including a select MISFET (Metal Insulator Semiconductor Field Effect Transistor) and a capacitive element coupled in series with the select MISFET. The select MISFET includes a gate electrode and a semiconductor region including a source region and a drain region. The capacitive element is coupled to the source region or the drain region of the select MISFET.

In the eDRAM, the source region and the drain region of the select MISFET are formed in a semiconductor substrate and a silicide film is formed on the surfaces of the source region and the drain region. The silicide film is formed at a distance from the side wall of the gate electrode, the distance being equivalent to the width of a side wall insulating film. In other words, the silicide film is separated from a channel region (channel forming region) according to the width of the side wall insulating film.

Japanese Unexamined Patent Application Publication No. Hei 10(1998)-294457 discloses a technique for preventing short circuits between a gate electrode and a source region or between the gate electrode and a drain region when a silicon film is selectively grown on the surfaces of the gate electrode and the source and drain regions of a MOSFET (Metal Oxide Semiconductor Field Effect Transistor).

### SUMMARY

For example, in eDRAM, size reduction of select MISFETs needs to reduce the width of a side wall insulating film and the sizes of a source region and a drain region. Thus, a silicide film formed on the surfaces of a source region and a drain region may come close to a channel region or the silicide film may come close to a boundary between the source region or the drain region and a well region, unfortunately increasing a leak current between the source region or the drain region and the well region so as to deteriorate the charge retention characteristics of DRAM cells.

Hence, a technique is necessary for improving charge retention characteristics in a semiconductor integrated circuit (IC) device including DRAM cells.

Other problems and novel features of the present invention will be clarified by the description herein and the accompanying drawings.

According to an embodiment, a semiconductor integrated circuit (IC) device including a MISFET has a first semiconductor region formed on an end of a gate electrode so as to extend into a semiconductor substrate, a second semiconductor region that is provided on the main side of the semiconductor substrate and is formed on a silicon film having a top surface, and a side wall insulating film partially covering the side wall of the gate electrode and the top surface of the silicon film. The semiconductor integrated circuit (IC) device further includes a silicide film formed on the top surface of the silicon film exposed from the side wall insulating film. The second semiconductor region has the same conductivity type as the first semiconductor region and has a higher concentration than the first semiconductor region. The first and second semiconductor regions include the source region or the drain region of the MISFET.

According to the embodiment, the charge retention characteristics of the semiconductor integrated circuit (IC) device can be improved.

### BRIEF DESCRIPTION OF THE DRAWINGS

FIG. 1 is a plan view showing the configuration of a semiconductor integrated circuit (IC) device according to an embodiment;

FIG. 2 is a cross-sectional view showing a principal part of a DRAM region and a logic circuit region of the semiconductor integrated circuit (IC) device according to the embodiment;

FIG. 3 is a cross-sectional view showing a principal part in a method of manufacturing the semiconductor integrated circuit (IC) device according to the embodiment;

FIG. 4 is a cross-sectional view showing a principal part in the manufacturing process of the semiconductor integrated circuit (IC) device after FIG. 3;

FIG. 5 is a cross-sectional view showing a principal part in the manufacturing process of the semiconductor integrated circuit (IC) device after FIG. 4;

FIG. 6 is a cross-sectional view showing a principal part in the manufacturing process of the semiconductor integrated circuit (IC) device after FIG. 5;

FIG. 7 is a cross-sectional view showing a principal part in the manufacturing process of the semiconductor integrated circuit (IC) device after FIG. 6;

FIG. 8 is a cross-sectional view showing a principal part in the manufacturing process of the semiconductor integrated circuit (IC) device after FIG. 7;

FIG. 9 is a cross-sectional view showing a principal part in the manufacturing process of the semiconductor integrated circuit (IC) device after FIG. 8;

FIG. 10 is a cross-sectional view showing a principal part in the manufacturing process of the semiconductor integrated circuit (IC) device after FIG. 9;

FIG. 11 is a cross-sectional view showing a principal part in the manufacturing process of the semiconductor integrated circuit (IC) device after FIG. 10; and

FIG. 12 is a cross-sectional view showing a principal part in the manufacturing process of the semiconductor integrated circuit (IC) device after FIG. 11.

### DETAILED DESCRIPTION

An embodiment will be specifically described below in accordance with the accompanying drawings. In all the explanatory drawings of the present embodiment, members having the same functions are indicated by the same reference numerals and a repeated explanation thereof is omitted. Moreover, in the present embodiment, identical or similar parts will not be repeatedly explained in principle unless otherwise required.

In the drawings used in the present embodiment, hatching may be omitted for clarification even in the cross-sectional view. Alternatively, even the plan view may be hatched for clarification.

### Embodiment

### <Structure of a Semiconductor Integrated Circuit (Ic) Device>

A semiconductor integrated circuit (IC) device according to the present embodiment includes eDRAM.

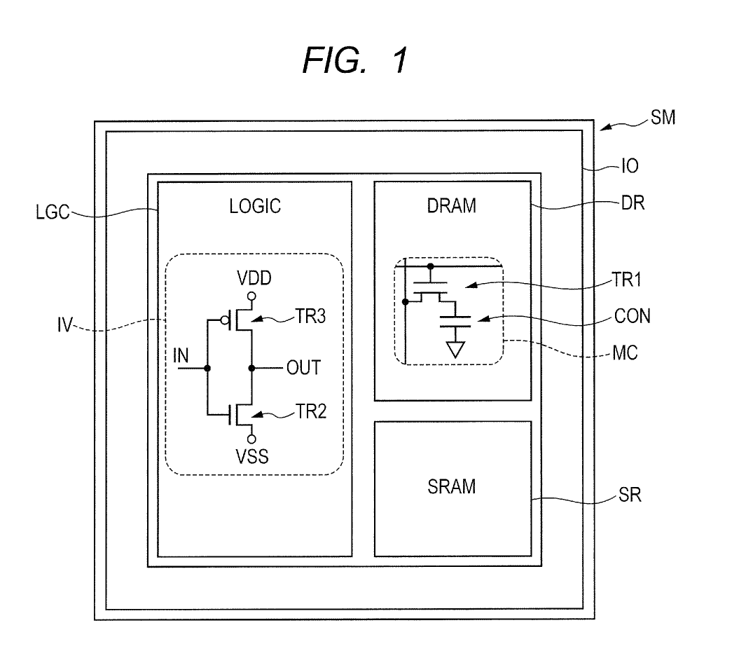

FIG. 1 is a plan view showing the configuration of a semiconductor integrated circuit (IC) device SM according to the present embodiment. The semiconductor integrated circuit (IC) device SM has a DRAM region DR having DRAM, an SRAM region SR having SRAM (Static Random Access Memory), a logic circuit region LGC having a logic circuit, and an I/O region IO having an I/O (Input/Output) circuit. The DRAM region DR has a DRAM cell array where DRAM cells are arranged in rows and columns. The DRAM cell includes an n-channel select MISFET (TR1) and a capacitive element CON coupled in series with the select MISFET. Hereinafter, the n-channel select MISFET may be a p-channel select MISFET. The logic circuit region LGC contains a logic circuit, e.g., an inverter circuit IV including an n-channel MISFET (TR2) and a p-channel MISFET (TR3) that are coupled in series.

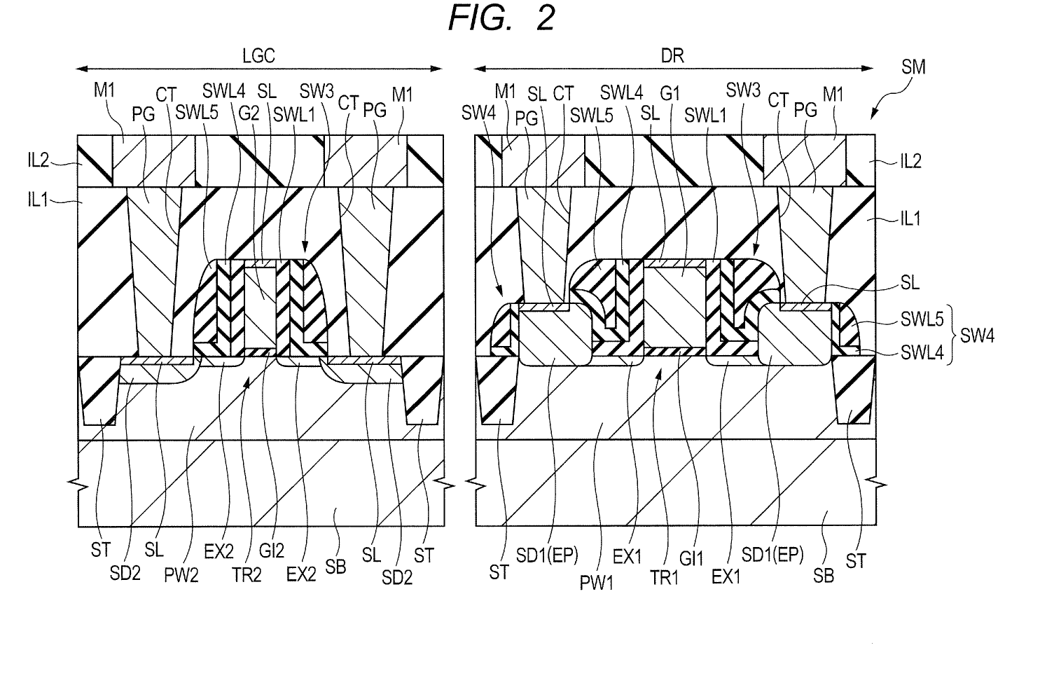

FIG. 2 is a cross-sectional view showing a principal part of the semiconductor integrated circuit (IC) device SM according to the present embodiment. FIG. 2 is a cross-sectional view showing a principal part of the select MISFET (TR1) in the DRAM region DR and the n-channel MISFET (TR2) in the logic circuit region LGC.

The semiconductor integrated circuit (IC) device SM is formed on a semiconductor substrate SB made of p-type silicon having a specific resistance of about 1 Ωcm to 10 Ωcm. The semiconductor substrate SB may be an SOI (Silicon On Insulator) substrate including a support substrate, an insulating layer, and a p-type silicon substrate that are stacked in this order. As a matter of course, the semiconductor substrate SB and the SOI substrate may be made of n-type silicon instead of p-type silicon.

A plurality of p-type well regions PW1 and PW2 are formed near the main side of the semiconductor substrate SB made of p-type silicon. The p-type well region PW1 contains the select MISFETs (TR1) while the p-type well region PW2 contains the n-channel MISFETs (TR2). FIG. 2 shows the single select MISFET (TR1) and the single n-channel MISFET (TR2). At least one n-type well region (not shown) may be provided so as to fully cover the p-type well regions PW1 and PW2 along the plane and depth of the semiconductor substrate SB. This configuration can electrically isolate the p-type semiconductor substrate SB, the p-type well region PW1, and the p-type well region PW2.

An element isolation film ST composed of an insulator, e.g., a silicon oxide film is formed from the main side of the semiconductor substrate SB in the depth direction of the semiconductor substrate SB. The element isolation film ST in the DRAM region DR is provided to electrically isolate the select MISFETs (TR1) formed in the p-type well region PW1. The element isolation film ST is formed around the forming region (will be called an active region) of the select MISFETs (TR1) in plan view. The element isolation film ST in cross section is continuously extended from the main side of the semiconductor substrate SB in the depth direction of the semiconductor substrate SB and is terminated at a smaller depth than the p-type well region PW1. The element isolation film ST in the logic circuit region LGC has the same configuration as the element isolation film ST in the DRAM region DR, electrically isolating the n-channel MISFETs (TR2) in the p-type well region PW2.

The select MISFET (TR1) includes a gate electrode G1, a source region, and a drain region. The gate electrode G1 is formed on the main side of the semiconductor substrate SB via a gate insulating film GI1, and a silicide film SL is formed on the gate electrode G1. The gate electrode G1 has a bottom in contact with the gate insulating film GI1 and a top surface located higher than the bottom according to the thickness of the gate electrode G1. The gate electrode G1 further includes side walls near the source and drain regions, respectively. In this configuration, the top surface of the gate electrode G1 means an interface between the gate electrode G1 and the silicide film SL.

The source region and the drain region have identical structures, each including n⁻-type semiconductor regions EX1 and an n⁺-type semiconductor region SD1 having a higher impurity concentration than the n⁻-type semiconductor region EX1. The two n⁻-type semiconductor regions EX1 including the source region and the drain region are formed inward with a predetermined depth from the main side of the semiconductor substrate SB so as to hold the gate electrode G1. A channel region (channel forming region) is a region between the two n⁻-type semiconductor regions EX1, that is, a region under the gate insulating film GI1. In the cross-sectional view, the n⁺-type semiconductor region SD1 including the source region and the drain region is formed on the main side of the semiconductor substrate SB and a silicon film EP formed on the main side of the semiconductor substrate SB, in a region between the n⁻-type semiconductor region EX1 and the element isolation film ST. In other words, the n⁺-type semiconductor region SD1 includes a portion formed in the semiconductor substrate SB and a part formed on the silicon film EP in the thickness direction of the silicon film EP. The overall silicon film EP includes a part of the n⁺-type semiconductor region SD1. The portion of the n⁺-type semiconductor region SD1 in the semiconductor substrate SB is equivalent to the depth of the n⁻-type semiconductor region EX1 and reduces the resistances of the source region and the drain region. The n⁺-type semiconductor region SD1 may have a smaller depth than the n⁻-type semiconductor region EX1 as long as the n⁺-type semiconductor region SD1 is partially formed in the semiconductor substrate SB.

The silicon film EP has a bottom in contact with the main side of the semiconductor substrate SB and a top surface located higher than the bottom according to the thickness of the silicon film EP. The silicon film EP further includes side walls coupling the bottom and the top surface. The main side of the semiconductor substrate SB is eroded during the manufacturing process and thus may vary depending on the location. Since an interface between the silicon film EP and the semiconductor substrate SB may not be clarified, the main side of the semiconductor substrate SB in the region of the gate insulating film GI1 (in other words, an interface between the gate insulating film GI1 and the main side of the semiconductor substrate SB) serves as a reference plane. In short, the reference plane serves as the main side of the semiconductor substrate SB in all the regions.

The silicide film SL having a desired thickness is formed on the top surface of the silicon film EP, that is, the surface of the n⁺-type semiconductor region SD1. The silicide film SL has a bottom near the reference plane and a top surface separated from the bottom according to the thickness of the silicide film SL. The bottom of the silicide film SL is located higher than the bottom of the silicon film EP (higher than the bottom of the gate electrode G1), thereby separating the silicide film EP from the channel region so as to reduce a leak current. Moreover, the top surface of the silicon film EP and the top surface of the silicide film SL are located lower than the top surface of the gate electrode G1, thereby reducing the resistances of the source region and the drain region. In other words, this configuration can reduce an increase in the thickness of the silicon film EP from preventing an increase in resistance in the source region and the drain region.

A side wall insulating film SW3 electrically isolates the gate electrode G1 and the silicon film EP. The side wall insulating film SW3 has a laminated structure including an insulating film SWL1, an insulating film SWL4, and an insulating film SWL5. The insulating film SWL1 is formed like a letter L along the side wall of the gate electrode G1 and the main side of the semiconductor substrate SB. The insulating film SWL4 and the insulating film SW5 are sequentially stacked on the insulating film SWL1. The insulating film SWL4 and the insulating film SWL5 partially cover the top surface of the silicon film EP. In the cross section of FIG. 2, the silicon film EP has two side walls coupling the top surface and the bottom such that the side wall near the gate electrode G1 is covered with the side wall insulating film SW3 including the insulating film SWL1, the insulating film SWL4, and the insulating film SWL5. The side wall remote from the gate electrode G1 is covered with a side wall insulating film SW4 including the insulating film SWL4 and the insulating film SWL5. The side wall insulating film SW4 is located on the element isolation film ST. The silicide film SL on the top surface of the silicon film EP (in other words, the surface of the n⁺-type semiconductor region SD1) is formed in a region exposed from the side wall insulating film SW3 and the side wall insulating film SW4.

The side wall remote from the gate electrode G1 of the silicon film EP is covered with the side wall insulating film SW4 and the silicide film SL is not formed on the side wall of the silicon film EP. In other words, the silicide film SL is formed only on the top surface of the silicon film EP but is not formed on the side walls, thereby preventing the silicide film SL approaching the boundary between the n⁺-type semiconductor region SD1 and the p-type well PW1 from increasing a leak current.

Since the silicon film EP is not formed on the top surface of the gate electrode G1, an electrical short circuit can be prevented between the gate electrode G1 and the source region or the drain region.

The n-channel MISFET (TR2) includes a gate electrode G2, a source region, and a drain region. The gate electrode G2 is formed on the main side of the semiconductor substrate SB via a gate insulating film GI2, and the silicide film SL is formed on the gate electrode G2. The gate electrode G2 has a bottom in contact with the gate insulating film GI2 and a top surface located higher than the bottom according to the thickness of the gate electrode G2. The gate electrode G2 further includes side walls near the source and drain regions, respectively.

The source region and the drain region have identical structures, each including n⁻-type semiconductor regions EX2 and an n⁺-type semiconductor region SD2 having a higher impurity concentration than the n⁻-type semiconductor region EX2. The two n⁻-type semiconductor regions EX2 including the source region and the drain region are formed on the main side of the semiconductor substrate SB so as to hold the gate electrode G2. A channel region (channel forming region) is a region between the two n⁻-type semiconductor regions EX2 on the main side of the semiconductor substrate SB, that is, a region under the gate insulating film GI1. The n⁺-type semiconductor region SD2 including the source region and the drain region is a region between the n⁻-type semiconductor region EX2 and the element isolation film ST, and is formed on the main side of the semiconductor substrate SB. The silicide film SL having a desired thickness is formed on the surface of the n⁺-type semiconductor region SD2 that is extended inward from the main surface of the semiconductor substrate SB. Thus, the top surface or bottom of the silicide film SL is located lower than the bottom of the gate electrode G2.

The side wall insulating film SW3 is formed on the side wall of the gate electrode G2. The side wall insulating film SW3 has a laminated structure including the insulating film SWL1, the insulating film SWL4, and the insulating film SWL5.

A comparison between the select MISFET (TR1) of the DRAM region DR and the n-channel MISFET (TR2) of the logic circuit region LGC will be described below.

The source region and the drain region of the select MISFET (TR1) are formed on the silicon film EP that is formed on the main side of the semiconductor substrate SB, whereas the source region and the drain region of the n-channel MISFET (TR2) are formed inward from the main side of the semiconductor substrate SB without the silicon film EP formed on the main side of the semiconductor substrate SB.

The gate length of the select MISFET (TR1) is longer than that of the gate electrode G2 of the n-channel MISFET (TR2). The gate electrode G1 of the select MISFET (TR1) has an extended gate length to reduce a leak current while the gate electrode G2 of the n-channel MISFET (TR2) is reduced in gate length to perform high-speed operations.

The side wall insulating film SW3 of the select MISFET (TR1) and the side wall insulating film SW3 of the n-channel MISFET (TR2) are identical in width.

In order to increase the on current of the n-channel MISFET (TR2), the n⁻-type semiconductor region EX2 desirably has a higher impurity concentration than the n⁻-type semiconductor region EX1. If the n⁻-type semiconductor region EX2 has a higher impurity concentration than the n⁻-type semiconductor region EX1, a halo (pocket) region that is a p-type region having a higher impurity concentration than the p-type well PW2 may be provided between the channel region and the n⁻-type semiconductor region EX2 of the n-channel MISFET (TR2). Even if the gate length of the gate electrode G2 of the n-channel MISFET (TR2) and the width of the side wall insulating film SW3 are reduced according to a size reduction of the device, the provision of the halo region can reduce a leak current called GIDL (Gate Induced Drain Leakage). However, the halo region is not formed on the select MISFET (TR1) of the DRAM region DR. The impurity concentration of the n⁻-type semiconductor region EX2 of the n-channel MISFET (TR2) may be equal to that of the n⁻-type semiconductor region EX1 of the select MISFET (TR1).

The select MISFET (TR1) and the n-channel MISFET (TR2) are covered with an interlayer insulating film IL1 having a plurality of contact holes CT. The contact hole CT contains a plug electrode PG composed of a conductive film. In the DRAM region DR, the plug electrode PG is electrically coupled in contact with the silicide film SL that is formed on the surfaces of the source region and the drain region of the select MISFET (TR1). In the logic circuit region LGC, the plug electrode PG is electrically coupled in contact with the silicide film SL that is formed on the surfaces of the source region and the drain region of the n-channel MISFET (TR2).

An interlayer insulating film IL2 is formed on the interlayer insulating film IL1. The interlayer insulating film IL2 contains a plurality of wires M1. In the DRAM region DR, the wires M1 are electrically coupled to the plug electrodes PG coupled to the source region and the drain region of the select MISFET (TR1). Moreover, in the logic circuit region LGC, the wires M1 are electrically coupled to the plug electrodes PG that are coupled to the source electrode or the drain region of the n-channel MISFET (TR2).

### <Main Effects on the Structure of the Semiconductor Integrated Circuit (IC) Device>

The silicon film EP serving as the source region or the drain region is provided on the main side of the semiconductor substrate SB, and the silicide film SL is provided on the top surface of the silicon film EP. Furthermore, the side wall insulating film SW3 formed on the side wall of the gate electrode G1 is placed on the top surface of the silicon film EP while the silicide film SL is formed on the top surface of the silicon film EP exposed from the side wall insulating film SW3. This configuration can separate the bottom of the silicide film SL from the channel region according to the thickness of the silicide film SL and the width of the side wall insulating film SW3 placed on the top surface of the silicon film EP, thereby reducing a leak current between the source region or the drain region and the p-type well region PW1. Moreover, the side wall insulating film SW3 of the select MISFET (TR1) can be reduced in width like the side wall insulating film SW3 of the n-channel MIFET (TR1), thereby simultaneously reducing the size of the select MISFET (TR1).

The silicon film EP serving as the source region or the drain region is formed on the main side of the semiconductor substrate SB, and the n⁺-type semiconductor region SD1 is provided inward from the top surface of the silicon film EP. The silicide film SL is formed only on the top surface of the silicon film EP while the side walls of the silicon film EP are covered with the side wall insulating films SW3 and SW4 but are not covered with the silicide film SL. This configuration increases a distance from the bottom of the silicide film SL to a boundary between the source region or the drain region and the p-type well region PW1 according to the thickness of the silicide film SL, thereby reducing a leak current between the source region or the drain region and the p-type well region PW1.

The bottom of the silicide film SL formed on the top surface of the silicon film EP is located higher than the bottom of the gate electrode G1, thereby further separating the bottom of the silicide film SL from the channel region. Moreover, the bottom of the silicide film SL can be separated from the boundary between the n⁺-type semiconductor region SD1 and the p-type well region PW1.

The top surface of the silicon film EP and the top surface of the silicide film SL are located lower than the top surface of the gate electrode G1, thereby reducing the resistances of the source region and the drain region.

The n⁺-type semiconductor region SD1 including the source region or the drain region is formed into the semiconductor substrate SB from the silicon film EP, thereby reducing the resistance of the source region or the drain region.

The source region and the drain region of the select MISFET (TR1) including the DRAM cell are formed on the silicon film EP that is formed on the main side of the semiconductor substrate SB while the source region and the drain region of the n-channel MISFET (TR2) of the logic circuit region LGC are formed in the semiconductor substrate SB. With this configuration, in the select MISFET (TR1), the silicide film SL formed on the surfaces of the source region and the drain region can be separated from the channel region, thereby reducing a leak current (in other words, the charge retention characteristics of the DRAM cell can be improved). Furthermore, the n-channel MISFET (TR2) includes the source region and the drain region without the silicon film EP. This can reduce the resistances of the source region and the drain region and achieve high-speed operations for the n-channel MISFET (TR2).

In addition to the configuration, the gate length of the select MISFET (TR1) is longer than that of the n-channel MISFET (TR2) while the n-channel MISFET (TR2) has a minimum gate length. This can perform the high-speed operations of the n-channel MISFET (TR2) (in other words, a logic circuit) while keeping the charge retention characteristics of the DRAM cell.

The source region and the drain region of the select MISFET (TR1) including the DRAM cell are formed in the silicon film EP that is formed on the main side of the semiconductor substrate SB while the source region and the drain region of the n-channel MISFET (TR2) of the logic circuit region LGC are formed in the semiconductor substrate SB. Moreover, the width of the side wall insulating film SW3 covering the side wall of the gate electrode G1 is equal to that of the side wall insulating film SW3 covering the side wall of the gate electrode G2. The side wall insulating film SW3 covering the side wall of the gate electrode G1 is placed on the top surface of the silicon film EP. Moreover, the silicide film SL is formed on the top surface of the silicon film EP exposed from the side wall insulating film SW3 placed on the top surface of the silicon film EP. This can reduce the size of the select MISFET (TR1) including the DRAM cell and the size of the n-channel MISFET (TR2) of the logic circuit region LGC, improve the charge retention characteristics of the DRAM cell, and achieve high-speed operations for the n-channel MISFET (TR2).

### <The Manufacturing Process of the Semiconductor Integrated Circuit (IC) Device>

A method of manufacturing the semiconductor integrated circuit (IC) device according to the present embodiment will be described below.

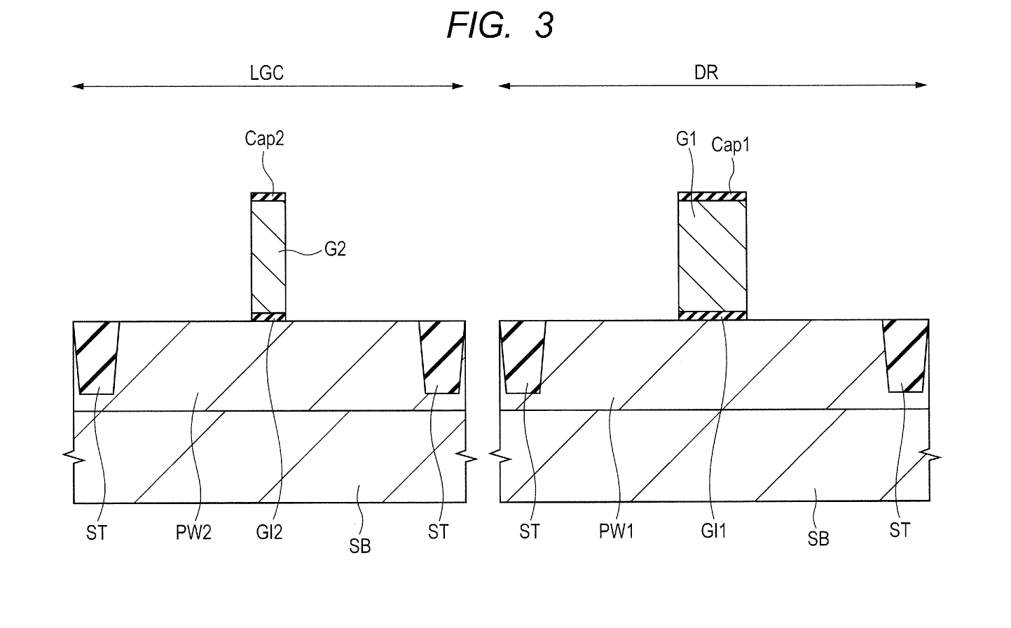

FIGS. 3 to 12 are cross-sectional views showing the principal part of the semiconductor integrated circuit (IC) device in the manufacturing process according to the present embodiment. FIGS. 3 to 12 are cross-sectional views showing the principal part of the select MISFET (TR1) of the DRAM region DR and the principal part of the n-channel MISFET (TR2) of the logic circuit region LGC.

First, the semiconductor substrate SB having the DRAM region DR and the logic circuit region LGC is prepared. The DRAM region DR of the semiconductor substrate SB contains the p-type well region PW1 that forms the select MISFET (TR1) and the element isolation film ST that determines a planar active region for forming the select MISFET (TR1). The logic circuit region LGC of the semiconductor substrate SB contains the p-type well region PW2 that forms the n-channel MISFET (TR2) and the element isolation film ST that determines a planar n-channel MISFET (TR2).

FIG. 3 shows the step of forming the gate electrodes G1 and G2. In the DRAM region DR, the gate insulating film GI1, the gate electrode G1, and a cap insulating film Cap1 are formed on the main side of the semiconductor substrate SB, whereas in the logic circuit region LGC, the gate insulating film GI2, the gate electrode G2, and a cap insulating film Cap2 are formed on the main side of the semiconductor substrate SB. The gate insulating film GI1, the gate electrode G1, and the cap insulating film Cap1 are equally flat. Moreover, the gate insulating film GI2, the gate electrode G2, and the cap insulating film Cap2 are equally flat. In the cross section of FIG. 3, the gate electrode G1 is wider (larger in width) than the gate electrode G2. The gate insulating films GI1 and GI2 are each composed of a silicon oxide film or silicon oxynitride film with a thickness of, for example, 2 nm to 3 nm. The gate electrodes G1 and G2 are each composed of a polycrystalline silicon film with a thickness of, for example, 80 nm to 100 nm. The cap insulating films Cap1 and Cap2 are each composed of a silicon nitride film with a thickness of, for example, 30 nm to 50 nm.

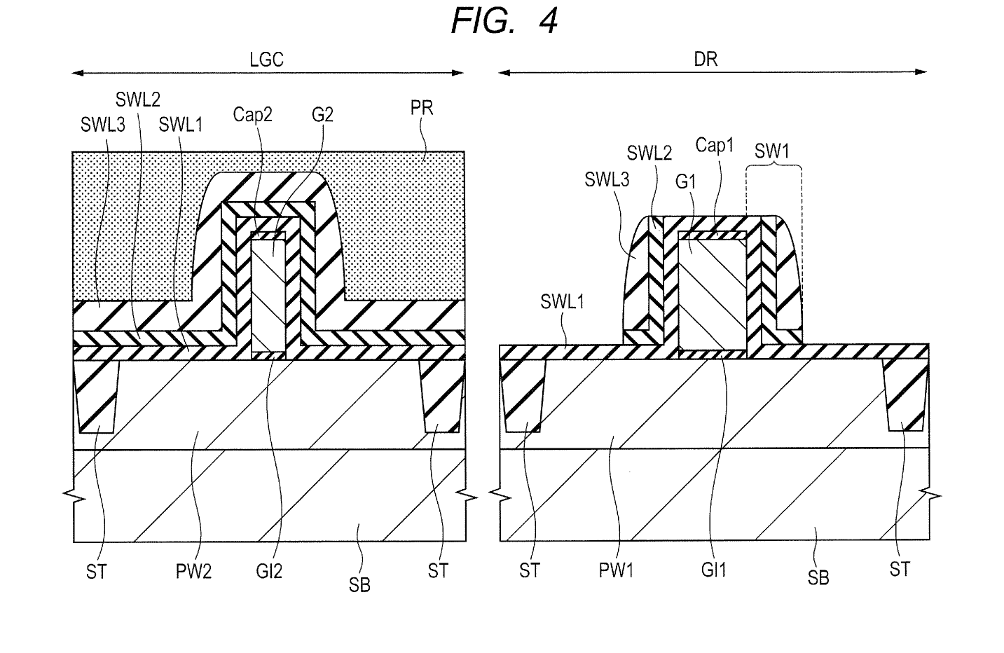

FIG. 4 shows the step of forming the side wall insulating film SW1. The insulating film SWL1, the insulating film SWL2, and the insulating film SWL3 are sequentially formed by, for example, plasma CVD (Chemical Vapor Deposition) so as to cover the laminated structure of the gate insulating film GI1, the gate electrode G1, and the cap insulating film Cap1 that are formed in the DRAM region DR and the laminated structure of the gate insulating film GI2, the gate electrode G2, and the cap insulating film Cap2 that are formed in the logic circuit region LGC. The insulating film SWL1 is composed of, for example, a silicon oxide film having a thickness of about 3 nm to 10 nm. The insulating film SWL2 is composed of, for example, a silicon nitride film having a thickness of about 3 nm to 10 nm. The insulating film SWL3 is composed of, for example, a silicon oxide film having a thickness of about 20 nm to 60 nm.

Subsequently, the logic circuit region LGC is covered with, for example, a resist film PR (mask film), and the insulating film SWL3 and the insulating film SWL2 of the DRAM region DR are sequentially subjected to anisotropic dry etching while the DRAM region DR is exposed. This forms the side wall insulating film SW1 on the side wall of the gate electrode G1. In the anisotropic dry etching process, the insulating film SWL3 is first subjected to anisotropic dry etching with CF₄ gas and so on. Subsequently, the gas is changed to, for example, CH₂F₂ gas to perform anisotropic dry etching on the insulating film SWL2. In the anisotropic dry etching process of the insulating film SWL2, the insulating film SWL1 under the insulating film SWL2 is slightly etched but is not fully exposed. Thus, the main side of the semiconductor substrate SB is not exposed. Specifically, the insulating film SWL2 is subjected to anisotropic dry etching on condition that the insulating film SWL2 has a larger etching rate than the insulating film SWL1. After the completion of processing on the insulating film SWL2, anisotropic dry etching on the insulating film SWL2 is completed with the insulating film SWL1 remaining on the main side of the semiconductor substrate SB. For example, the side wall insulating film SW1 has a width of about 15 nm. A distance between the silicon film EP and the gate electrode G1, which will be described later, is determined by the width of the side wall insulating film SW1.

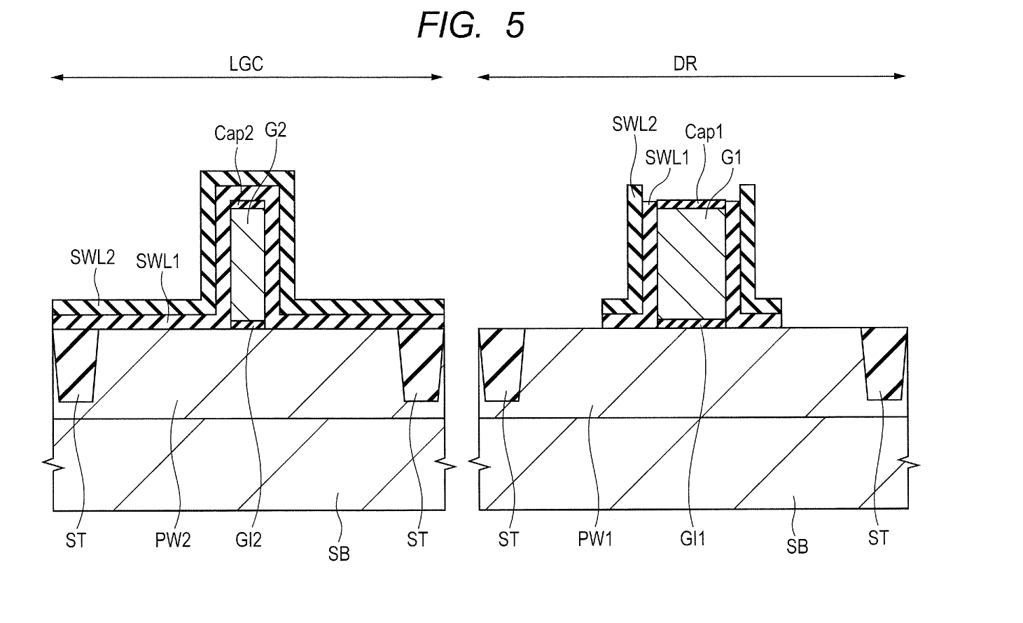

FIG. 5 shows the step of etching the insulating film SWL1. This step may be called the exposing step of the main side of the semiconductor substrate SB. After the resist film PR covering the logic circuit region LGC is removed, the insulating film SWL1 covering the main side of the semiconductor substrate SB is removed by wet etching so as to expose the main side of the semiconductor substrate SB in a region between the side wall insulating film SW1 and the element isolation film ST in the DRAM region DR. In the wet etching, an etchant of fluorinated acid is used to simultaneously remove the insulating film SWL3 including the side wall insulating film SW1 in the DRAM region DR and the insulating film SWL3 in the logic circuit region LGC. The wet etching is performed on condition that the silicon oxide film has a larger etching rate than the silicon nitride film, thereby etching the insulating film SWL1 while the insulating film SWL2 including the side wall insulating film SW1 serves as a mask. Specifically, in the DRAM region DR, the insulating film SWL1 is removed by etching from a region between the side wall insulating film SW1 and the element isolation film ST and the top of the gate electrode G1. During the etching, the insulating film SWL1 on the side wall of the cap insulating film Cap1 is simultaneously eroded by etching but the etching is stopped while the amount of erosion is within the thickness range of the cap insulating film Cap1. This can prevent exposure of the gate electrode G1. In other words, the cap insulating film Cap1 is provided to prevent the wet etching from exposing the gate electrode G1. Moreover, the wet etching is performed on condition that the silicon oxide film has a larger etching rate than silicon including the semiconductor substrate SB. Thus, the main side of the semiconductor substrate SB is hardly eroded. The cap insulating film Cap1 also prevents the formation of the silicon film EP, which will be described later, on the gate electrode G1.

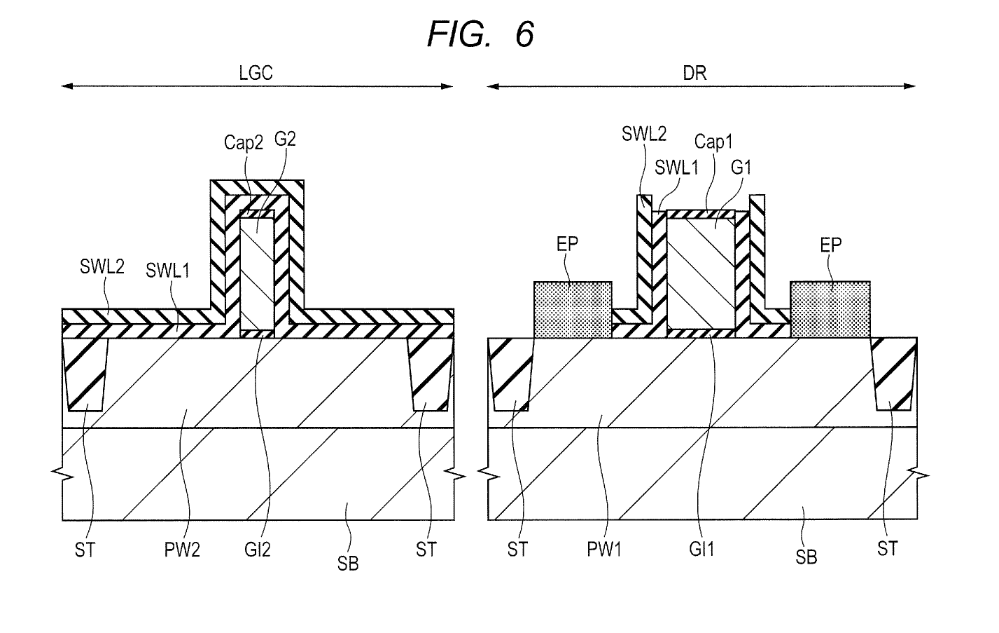

FIG. 6 shows the step of forming the silicon film EP. The silicon film EP is formed on the main side of the exposed semiconductor substrate SB by epitaxial growth. The silicon film EP is selectively formed in a region between the side wall insulating film SW1 (in other words, the insulating film SWL2) and the element isolation film ST of the DRAM region DR, the silicon film EP having a thickness of, for example, about 30 nm to 50 nm. The silicon film EP is not formed on the gate electrode G1 of the select MISFET (TR1) or in the logic circuit region LGC.

Subsequently, the insulating film SWL2 is removed by, for example, chemical dry etching so as to expose the insulating film SWL1 in the DRAM region DR and the logic circuit region LGC.

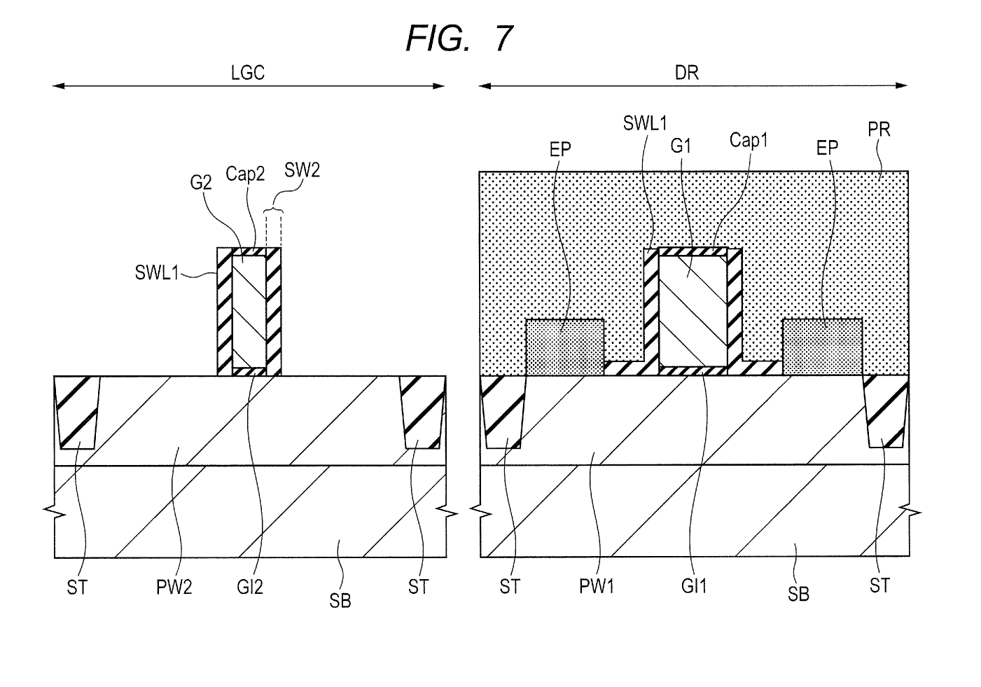

FIG. 7 shows the step of forming the side wall insulating film SW2. After the exposure of the insulating film SWL1, the DRAM region DR is selectively covered with the resist film PR. In this state, the insulating film SWL1 of the logic circuit region LGC is subjected to anisotropic dry etching, forming the side wall insulating film SW2 on the side wall of the gate electrode G2. Subsequently, the resist film PR is removed, and then the cap insulating films Cap1 and Cap2 are removed by, for example, chemical dry etching in the DRAM region DR and the logic circuit region LGC, exposing the top surfaces of the gate electrodes G1 and G2.

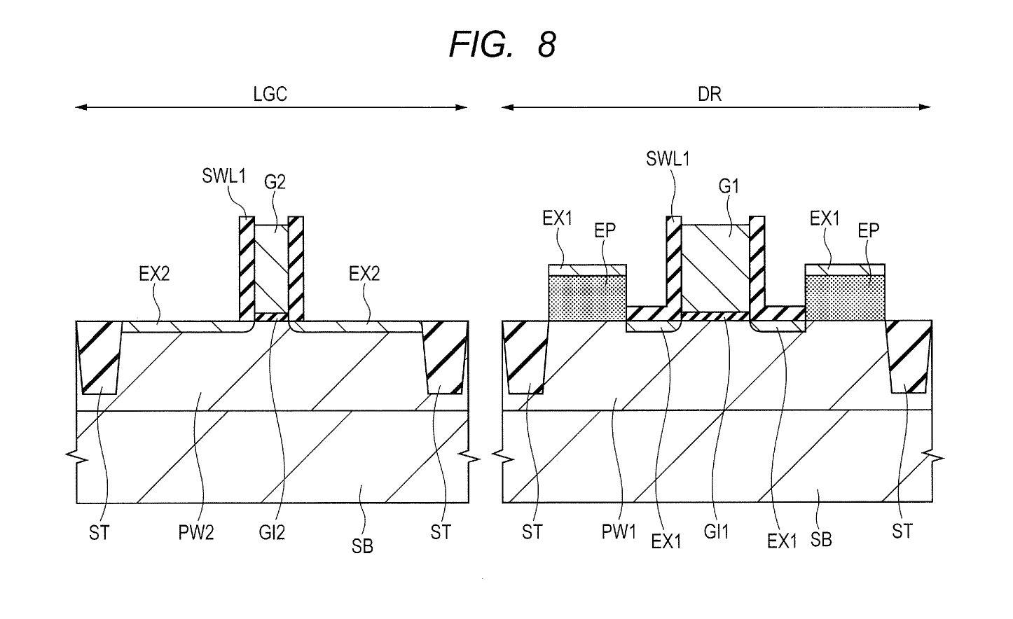

FIG. 8 shows the step of forming the n⁻-type semiconductor regions EX1 and EX2. In the DRAM region DR and the logic circuit region LGC, an n-type impurity, e.g., phosphorus is introduced to the main side of the semiconductor substrate SB by ion implantation, forming the n⁻-type semiconductor regions EX1 and EX2 in the semiconductor substrate SB on both sides of the gate electrodes G1 and G2. At this point, the n⁻-type semiconductor region EX1 is also formed on the top surface of the silicon film EP formed in the DRAM region DR. If the n⁻-type semiconductor region EX2 of the logic circuit region LGC has a higher impurity concentration than the n⁻-type semiconductor region EX1 of the DRAM region DR, the n⁻-type semiconductor region EX1 is formed by ion implantation of a low dose of a p-type impurity only to the DRAM region DR while the logic circuit region LGC is selectively covered with a resist film or the like. Subsequently, the n⁻-type semiconductor region EX2 is formed by ion implantation of a high dose of a p-type impurity only to the logic circuit region LGC while the DRAM region DR is selectively covered with a resist film or the like. Furthermore, a p-type impurity, e.g., boron is introduced only to the logic circuit region LGC by ion implantation while the DRAM region DR is selectively covered with a resist film or the like, thereby forming the halo (pocket) region between the n⁻-type semiconductor region EX2 and the channel region.

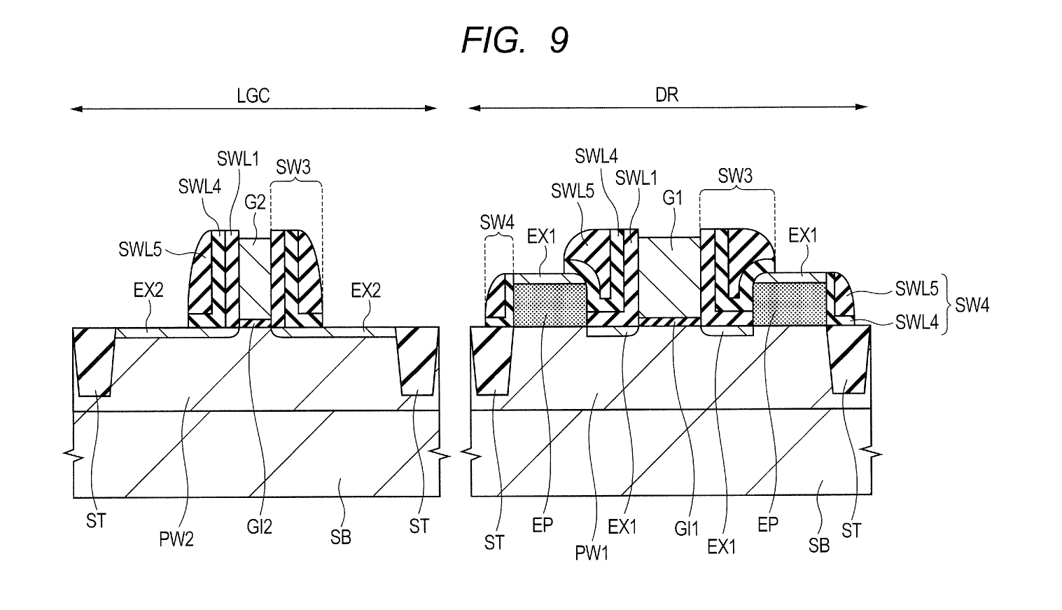

FIG. 9 shows the step of forming the side wall insulating films SW3 and SW4. After the n⁻-type semiconductor regions EX1 and EX2 are formed, the insulating film SWL4 and the insulating film SWL5 are formed on the main side of the semiconductor substrate SB by, for example, plasma CVD. The insulating film SWL4 is composed of, for example, a silicon nitride film having a thickness of about 3 nm to 10 nm while the insulating film SWL5 is composed of, for example, a silicon oxide film having a thickness of about 20 nm to 60 nm. Subsequently, the insulating film SWL5 and the insulating film SWL4 are subjected to anisotropic dry etching so as to form the side wall insulating film SW3 including the insulating film SWL1, the insulating film SWL4, and the insulating film SWL5 on the side walls of the gate electrodes G1 and G2. The side wall insulating film SW3 formed over the side wall of the gate electrode G1 covers the side wall of the silicon film EP near the gate electrode G1 and the top surface of the silicon film EP. In other words, the width of the side wall insulating film SW3 is larger than that of the side wall insulating film SW1 illustrated in FIG. 4. The side wall insulating film SW4 including the insulating films SWL4 and SWL5 is formed on the side wall of the silicon film EP remotely from the gate electrode G1. The insulating films SWL4 and SWL5 on the gate electrodes G1 and G2 are removed by anisotropic dry etching for forming the side wall insulating films SW3 and SW4. This exposes the top surfaces of the gate electrodes G1 and G2.

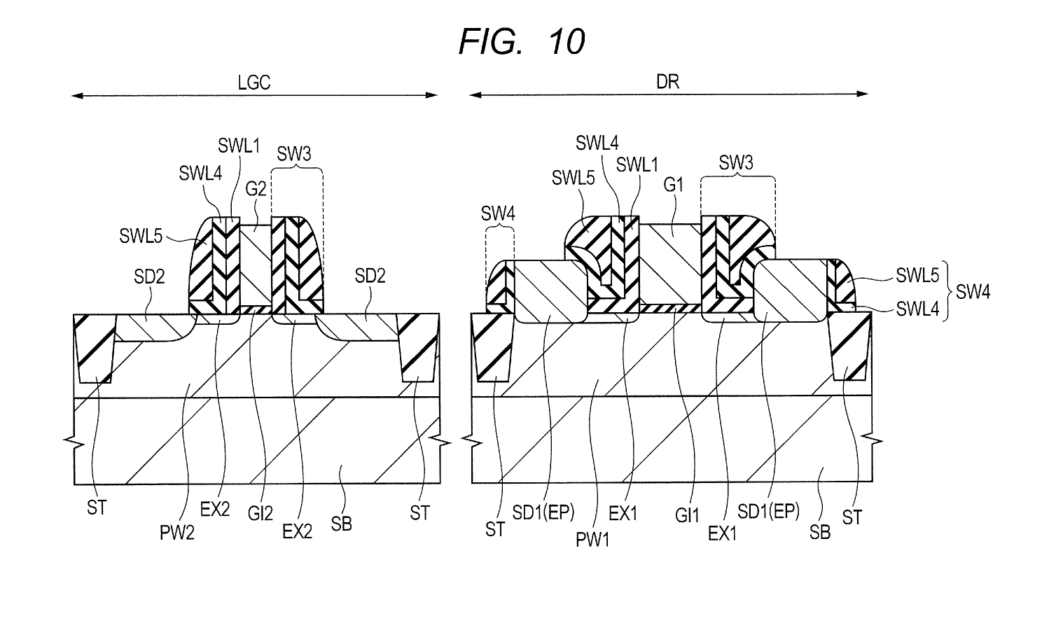

FIG. 10 shows the step of forming the n⁺-type semiconductor regions SD1 and SD2 n-type impurities such as phosphorus and arsenic are introduced by ion implantation to the main side of the semiconductor substrate SB and the top surface of the silicon film EP that are exposed from the side wall insulating films SW3 and SW4 and the element isolation film ST. After that, the impurities are heated to form the n⁺-type semiconductor regions SD1 and SD2. The n⁺-type semiconductor regions SD1 and SD2 have higher impurity concentrations than the n⁻-type semiconductor regions EX1 and EX2. In the DRAM region DR, the n-type impurities introduced into the silicon film EP are diffused over the silicon film EP, turning the overall silicon film EP into the n⁺-type semiconductor region SD1. Moreover, the n⁺-type semiconductor region SD1 is diffused as deep as the n⁻-type semiconductor region EX1 in the semiconductor substrate SB. The n⁺-type semiconductor region SD1 may have a smaller depth than the n⁻-type semiconductor region EX1 in the semiconductor substrate SB. The n⁺-type semiconductor region SD1 in contact with or overlapping with the n⁻-type semiconductor region EX1 in the depth direction can reduce the resistance of the source region or the drain region of the select MISFET (TR1).

In the logic circuit region LGC, the n⁺-type semiconductor region SD2 is formed inward from the main side of the semiconductor substrate SB.

The n⁺-type semiconductor region SD1 of the DRAM region DR and the n⁺-type semiconductor region SD2 of the logic circuit region LGC may be formed in different steps.

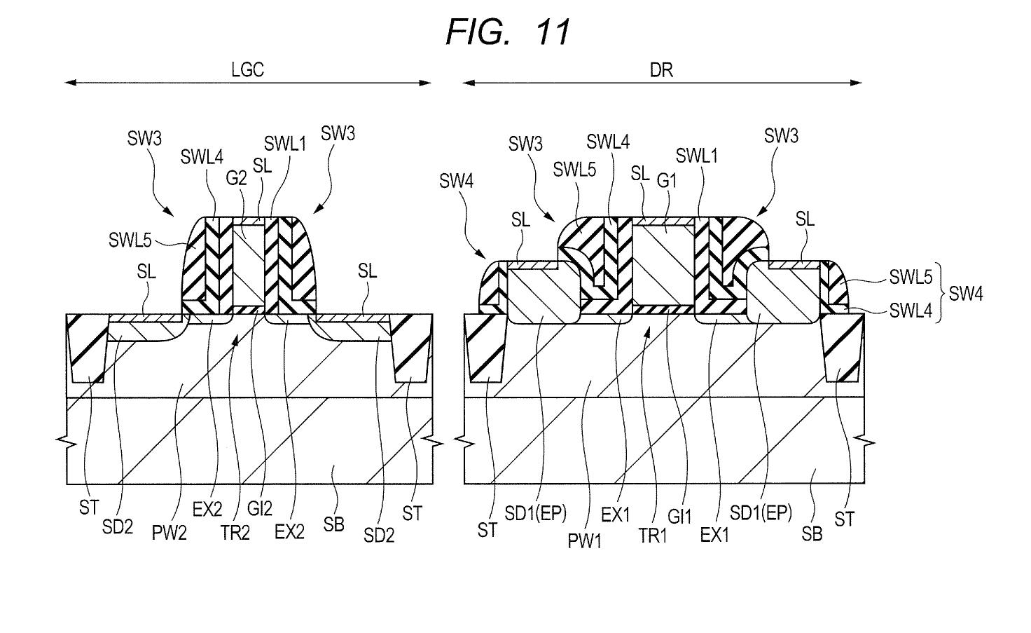

FIG. 11 shows the step of forming the silicide film SL. In the DRAM region DR, the silicide film SL is formed on the top surface of the silicon film EP exposed from the side wall insulating films SW3 and SW4 and the top surface of the gate electrode G1. In the logic circuit region LGC, the silicide film SL is formed on the main side of the semiconductor substrate SB exposed from the side wall insulating film SW3 and the element isolation film ST and the top surface of the gate electrode G2. The silicide film SL has a thickness of about 10 nm to 20 nm in the DRAM region DR and the logic circuit region LGC. The silicide film SL is made of, for example, cobalt silicide (CoSi₂), nickel silicide (NiSi), or nickel platinum silicide (NiPtSi).

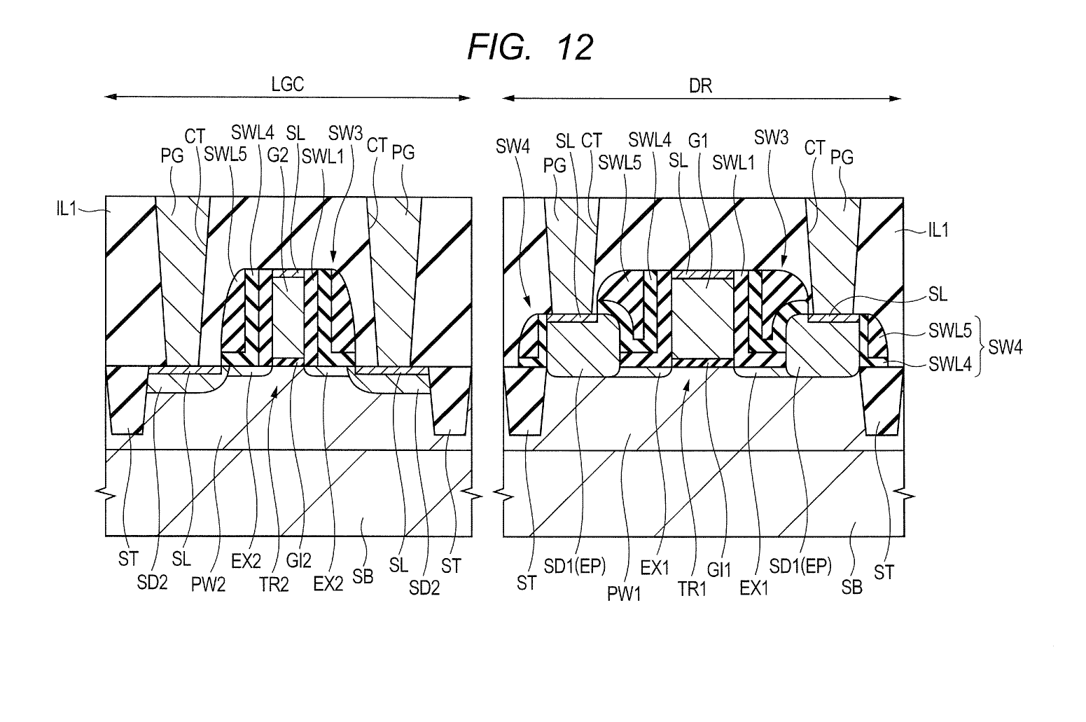

FIG. 12 shows the step of forming the interlayer insulating film IL1 and the plug electrode PG. The interlayer insulating film IL1 on the semiconductor substrate SB is formed by, for example, plasma CVD so as to cover the gate electrode G1, the source region, and the drain region of the select MISFET (TR1) and the gate electrode G2, the source region, and the drain region of the n-channel MISFET (TR2). The interlayer insulating film IL1 may be a single silicon oxide film or a laminated film of a silicon nitride film and a silicon oxide film. The surface of the interlayer insulating film IL1 is flattened by CMP (Chemical Mechanical Polishing).

Subsequently, the contact holes CT are formed on the interlayer insulating film IL1 so as to partially expose the silicide film SL formed in the source region and the drain region of the select MISFET (TR1) and the silicide film SL formed in the source region and the drain region of the n-channel MISFET (TR2), and then the plug electrodes PG are formed in the contact holes CT. The plug electrode PG has a laminated structure of a first barrier conductor film (e.g., a titanium film, a titanium nitride film, or a laminated film thereof) that is in contact with the silicide film SL and the interlayer insulating film IL1 and a first main conductor film (composed of, for example, a tungsten film) that is provided in the first barrier film.

After the step of forming the interlayer insulating film IL2 and the wires M1, the semiconductor integrated circuit (IC) device SM is completed as shown in FIG. 2. The interlayer insulating film IL2 composed of, for example, a silicon oxide film is formed on the interlayer insulating film IL1 by techniques such as plasma CVD so as to cover the plug electrodes PG. The wires M1 are embedded in the interlayer insulating film IL2. The wire M1 has a laminated structure of a second barrier conductor film (e.g., a titanium film, a titanium nitride film, or a laminated film thereof) that is in contact with the plug electrode PG and the interlayer insulating film IL2 and a second main conductor film (e.g., a copper film) that is provided in the barrier conductor film.

### <Main Effect of the Method of Manufacturing the Semiconductor Integrated Circuit (IC) Device>

In order to form the silicon film EP on the main side of the semiconductor substrate SB, the side wall insulating film SW1 is first formed on the side wall of the gate electrode G1. In the formation of the side wall insulating film SW1, the insulating films SWL3 and SWL2 including the side wall insulating film SW1 are processed by anisotropic dry etching. The anisotropic dry etching is completed when the insulating film SWL1 covering the main side of the semiconductor substrate SB remains. Subsequently, the insulating film SWL1 covering the main side of the semiconductor substrate SB is removed by wet etching, and then the silicon film EP is formed on the main side of the exposed semiconductor substrate SB by an epitaxial method.

The effects of the manufacturing method will be described below.

First, Japanese Unexamined Patent Application Publication No. Hei 10(1998)-294457 as a related art document discloses a technique of selectively growing a Si film on source and drain regions and a gate electrode after a side wall is formed on the side wall of the gate electrode by anisotropic dry etching. The related art document also discloses cleaning of a growth substrate with a chemical solution before a Si film is selectively grown.

In this manufacturing method, anisotropic dry etching during the formation of the side walls may cause physical damage (defects or the like) to the substrate. In the anisotropic dry etching process, fluorine (F) or carbon (C) that is contained in etching gas or fluorine (F) or carbon (C) that is contained in deposits on the side wall of an etching chamber may be ionized and implanted into the substrate. It is found that a solution to this problem is long wet treatment, cleaning on a substrate surface according to high-temperature hydrogen bake, or high-temperature epitaxial growth. It is also found that impurities such as fluorine (F) and carbon (C) are deeply implanted into the substrate and thus cannot be removed by ordinary cleaning.

The method of manufacturing the semiconductor integrated circuit (IC) device according to the present embodiment does not cause physical damage to the substrate or implant impurities such as fluorine (F) and carbon (C) into the substrate, allowing epitaxial growth at low temperatures. The absence of high-temperature hydrogen bake and high-temperature epitaxial growth can prevent enhanced diffusion of ion-implanted impurities, thereby reducing a leak current between the source region and the drain region. Since wet treatment is not performed for long hours, a leak current caused by erosion of the element isolation film ST can be reduced between the source region or the drain region and the substrate (or a well region).

Furthermore, the side wall insulating film SW3 of the select MISFET (TR1) and the side wall insulating film SW3 of the n-channel MISFET (TR2) can be formed in the same process, thereby achieving a short manufacturing process and lower manufacturing cost.

The inventions made by the present inventors were specifically described according to the embodiment. The present invention is not limited to the embodiment and can be changed in various ways within the scope of the invention.

What is claimed is:

1. A semiconductor integrated circuit (IC) device comprising a MISFET having a gate electrode, a source region, and a drain region,
the semiconductor integrated circuit (IC) device comprising:
a silicon semiconductor substrate having a main side;
the gate electrode formed over the main side with a gate insulating film interposed between the gate electrode and the main side;
a first semiconductor region formed on an end of the gate electrode so as to extend from the main side of the semiconductor substrate into the semiconductor substrate;
a silicon film having a top surface, the silicon film being formed over the main side of the semiconductor substrate so as to be separated from the gate electrode;
a first side wall insulating film that covers a first side wall of the gate electrode and a part of the top surface of the silicon film;
a second semiconductor region formed from the top surface of the silicon film into the silicon film; and
a silicide film that is exposed from the first side wall insulating film and is formed over the top surface of the silicon film,
the second semiconductor region having the same conductivity type as the first semiconductor region and a higher concentration than the first semiconductor region,
the first and second semiconductor regions including the source region or the drain region of the MISFET.

2. The semiconductor integrated circuit (IC) device according to claim 1,
wherein the silicon film has a second side wall near the gate electrode and a third side wall remote from the gate electrode, the second side wall being covered with the first side wall insulating film.

3. The semiconductor integrated circuit (IC) device according to claim 2,
wherein the third side wall is covered with a second side wall insulating film.

4. The semiconductor integrated circuit (IC) device according to claim 1,
wherein the silicide film has a bottom that is located higher than an interface between the gate insulating film and the gate electrode with reference to the main side of the semiconductor substrate in a region containing the gate insulating film.

5. The semiconductor integrated circuit (IC) device according to claim 1,
wherein the top surface of the silicon film is located lower than a second top surface of the gate electrode with reference to the main side of the semiconductor substrate in a region containing the gate insulating film.

6. A semiconductor integrated circuit (IC) device comprising:
a first MISFET that is formed in a first region of a main surface of a silicon semiconductor substrate and has a first gate electrode, a first source region, and a first drain region; and
a second MISFET that is formed in a second region different from the first region of the main side of the semiconductor substrate and has a second gate electrode, a second source region, and a second drain region,
the first MISFET including:
the first gate electrode formed over the main side with a first gate insulating film interposed between the main side and the first gate electrode;
a first semiconductor region formed on an end of the first gate electrode so as to extend from the main side of the semiconductor substrate into the semiconductor substrate;
a silicon film having a first top surface, the silicon film being formed over the main side of the semiconductor substrate so as to be separated from the first gate electrode;
a first side wall insulating film that covers a first side wall of the first gate electrode and a part of the top surface of the silicon film;
a second semiconductor region formed from the top surface of the silicon film into the silicon film; and
a first silicide film that is formed over the top surface of the silicon film exposed from the first side wall insulating film,
the second MISFET including:
the second gate electrode formed over the main side of the semiconductor substrate with a second gate insulating film interposed between the main side and the second gate electrode;
a third semiconductor region formed on an end of the second gate electrode so as to extend from the main side of the semiconductor substrate into the semiconductor substrate;
a second side wall insulating film that covers a second side wall of the second gate electrode;
a fourth semiconductor region formed, in a region exposed from the second side wall insulating film, from the main side of the semiconductor substrate into the semiconductor substrate; and
a second silicide film formed, in the region exposed from the second side wall insulating film, over a surface of the fourth semiconductor region,
the second semiconductor region having the same conductivity type as the first semiconductor region and a higher concentration than the first semiconductor region,
the fourth semiconductor region having the same conductivity type as the third semiconductor region and a higher concentration than the third semiconductor region,
the first and second semiconductor regions including the first source region or the first drain region of the first MISFET,
the third and fourth semiconductor regions including the second source region or the second drain region of the second MISFET.

7. The semiconductor integrated circuit (IC) device according to claim 6,
wherein the silicon film has a third side wall near the first gate electrode and a fourth side wall remote from the first gate electrode, the third side wall being covered with the first side wall insulating film.

8. The semiconductor integrated circuit (IC) device according to claim 7,
wherein the fourth side wall is covered with a third side wall insulating film.

9. The semiconductor integrated circuit (IC) device according to claim 6,
wherein the first silicide film has a bottom that is located higher than an interface between the first gate insulating film and the first gate electrode with reference to the main side of the semiconductor substrate in a region containing the first gate insulating film.

10. The semiconductor integrated circuit (IC) device according to claim 6,
wherein the top surface of the silicon film is located lower than a second top surface of the first gate electrode with reference to the main side of the semiconductor substrate in a region containing the first gate insulating film.

11. The semiconductor integrated circuit (IC) device according to claim 6,
wherein the second silicide film has a third top surface that is located lower than an interface between the second gate insulating film and the second gate electrode with reference to the main side of the semiconductor substrate in a region containing the second gate insulating film.

12. The semiconductor integrated circuit (IC) device according to claim 11,
wherein the bottom of the first silicide film is located higher than the third top surface of the second silicide film with reference to the main side of the semiconductor substrate in the region containing the first gate insulating film.

13. The semiconductor integrated circuit (IC) device according to claim 6,
wherein the first side wall insulating film and the second side wall insulating film are identical in width.

14. The semiconductor integrated circuit (IC) device according to claim 6,
wherein the second semiconductor region reaches the first semiconductor region from the top surface of the silicon film.

15. The semiconductor integrated circuit (IC) device according to claim 6, further comprising a capacitive element coupled to the first source region or the first drain region of the first MISFET.

16. A method of manufacturing a semiconductor integrated circuit (IC) device, comprising the steps of:
(a) preparing a silicon semiconductor substrate having a main side;
(b) forming a gate electrode over the main surface with a gate insulating film interposed between the gate electrode and the main side, the gate electrode having a top surface and a side wall;
(c) forming a first insulating film over the main side of the semiconductor substrate so as to cover the top surface and the side wall of the gate electrode;
(d) forming a first side wall insulating film having a first width by performing anisotropic dry etching on the first insulating film;
(e) forming a silicon film over the main side of the semiconductor substrate, in a region separated from the side wall of the gate electrode at least according to the first width;
(f) forming a second side wall insulating film having a second width from the side wall of the gate electrode such that the second side wall insulating film covers the side wall of the gate electrode and partially covers a top surface of the silicon film;
(g) forming a semiconductor region over the top surface of the silicon film, in a region exposed from the second side wall insulating film; and
(h) forming a silicide film over a surface of the semiconductor region, in the region exposed from the second side wall insulating film,
the second side wall insulating film partially covering the top surface of the silicon film.

17. The method of manufacturing a semiconductor integrated circuit (IC) device according to claim 16,
wherein the second width is larger than the first width.

18. The method of manufacturing a semiconductor integrated circuit (IC) device according to claim 16,
wherein the first insulating film has a laminated structure sequentially including a first silicon oxide film, a first silicon nitride film, and a second silicon oxide film from the main side of the semiconductor substrate, and
in (d), the main side of the semiconductor substrate is covered with the first silicon oxide film.

19. The method of manufacturing a semiconductor integrated circuit (IC) device according to claim 18,
wherein before (e), the method comprising the step of (i) removing the first silicon oxide film from the main side of the semiconductor substrate by wet etching.

20. The method of manufacturing a semiconductor integrated circuit (IC) device according to claim 16,
wherein in (f), a third side wall insulating film is formed over the side wall of the silicon film.

21. A method of manufacturing a semiconductor integrated circuit (IC) device including a first MISFET having a first gate electrode, a first source region, and a first drain region, and a second MISFET having a second gate electrode, a second source region, and a second drain region,
the method comprising the steps of:
(a) preparing a silicon semiconductor substrate having a first region and a second region different from the first region on a main side of the semiconductor substrate;
(b) forming the first gate electrode in the first region over the main side of the semiconductor substrate with a first gate insulating film interposed between the main side and the first gate electrode, and forming the second gate electrode in the second region over the main side of the semiconductor substrate with a second gate insulating film interposed between the main side and the second gate electrode;
(c) forming a first insulating film covering the first gate electrode of the first region and the second gate electrode of the second region, performing anisotropic dry etching on the first insulating film of the first region with the second region covered with a first mask, and forming a first side wall insulating film having a first width over a first side wall of the first gate electrode;
(d) forming a silicon film over the main side of the semiconductor substrate so as to be separated from the first side wall of the first gate electrode according to the first width, in the first region with the second region covered with the first insulating film;
(e) forming a second insulating film over the main side of the semiconductor substrate, performing anisotropic dry etching on the second insulating film, and forming a second side wall insulating film having a second width over the second side wall of the second gate electrode;
(f) forming a first semiconductor region in the first region over the silicon film exposed from the second side wall insulating film, and forming a second semiconductor region in the second region over the main side of the semiconductor substrate exposed from the second side wall insulating film; and
(g) forming a silicide film in the first semiconductor region exposed from the second side wall insulating film and a surface of the second semiconductor region,
the second width being larger than the first width,
the second side wall insulating film partially covering a top surface of the silicon film in the first region.

22. The method of manufacturing a semiconductor integrated circuit (IC) device according to claim 21,
wherein the first insulating film sequentially includes a first silicon oxide film, a first silicon nitride film, and a second silicon oxide film from the main side of the semiconductor substrate, anisotropic dry etching in (c) is performed on the second silicon oxide film and the first silicon nitride film, and the first silicon oxide film is removed by wet etching.

23. The method of manufacturing a semiconductor integrated circuit (IC) device according to claim 22,
wherein in wet etching for removing the first silicon oxide film, the second silicon oxide film of the first region and the second silicon oxide film of the second region are also removed.

24. The method of manufacturing a semiconductor integrated circuit (IC) device according to claim 23, wherein after (d), the method further comprises the steps of:
removing the first silicon nitride film in the first region and the second region;
forming a third side wall insulating film over the second side wall of the second gate electrode by performing anisotropic dry etching on the first silicon oxide film in the second region with the first region selectively covered with a second mask; and
forming a third semiconductor region over the main side of the semiconductor substrate, in a region uncovered with the second gate electrode and the third side wall insulating film in the second region.

25. The method of manufacturing a semiconductor integrated circuit (IC) device according to claim 21, wherein in (e), a fourth side wall insulating film is formed over a third side wall of the silicon film.
